(19) United States
(12) Patent Application Publication
(10) Pub. No.: US 2023/0019350 A1
(43) Pub. Date: Jan. 19, 2023

(54) SEMICONDUCTOR PACKAGES

(71) Applicant: SAMSUNG ELECTRONICS CO., LTD., Suwon-si (KR)

(72) Inventors: Wooseup HWANG, Daegu (KR); Hyeyeong JO, Suwon-si (KR)

(21) Appl. No.: 17/861,606

(22) Filed: Jul. 11, 2022

(30) Foreign Application Priority Data
Jul. 19, 2021 (KR) 10-2021-0094457

(51) Int. Cl. H01L 23/00; H01L 23/48

(52) U.S. Cl. CPC H01L 24/08; H01L 24/05; H01L 23/481; H01L 2224/08145; H01L 2224/05082; H01L 2224/05573; H01L 2224/05147; H01L 2224/05144; H01L 2224/05155; H01L 2224/05124; H01L 2224/05184; H01L 2224/05186; H01L 2224/05647

(57) ABSTRACT

A semiconductor package includes: a first semiconductor chip; a second semiconductor chip; and a bonding structure at an interface between the first and second semiconductor chips. The bonding structure includes: a first bonding insulating layer on the first semiconductor chip; a first connection pad in a first pad opening formed in the first bonding insulating layer, the first connection pad including a first pad layer, a first interface layer including a copper oxide, and a first capping layer; a second bonding insulating layer on the second semiconductor chip; and a second connection pad in a second pad opening formed in the second bonding insulating layer, the second connection pad including a second pad layer, a second interface layer including a copper oxide, and a second capping layer. The first and second capping layers include copper monocrystal layers having a (111) orientation.

### CROSS-REFERENCE TO RELATED APPLICATION

This application is based on and claims priority under 35 U.S.C. § 119 to Korean Patent Application No. 10-2021-0094457, filed on Jul. 19, 2021, in the Korean Intellectual Property Office, the disclosure of which is incorporated by reference herein in its entirety.

### BACKGROUND

The inventive concept relates to semiconductor packages, and more particularly, to semiconductor packages having a stacked structure of a plurality of semiconductor chips.

To improve the performance and storage capacity of semiconductor devices, semiconductor packages having a stacked structure of a plurality of semiconductor chips may be used. Particularly, the method of forming a stacked structure of a plurality of semiconductor chips by bonding a semiconductor chip on a wafer through a connection pad and sawing the wafer has been suggested. However, to bond a semiconductor chip through material diffusion between the connection pads, a bonding process of a relatively high temperature may need to be used.

### SUMMARY

The inventive concept provides semiconductor packages which facilitate a bonding process of connection pads at a relatively low temperature and include a bonding structure having a relatively low contact resistance.

According to an aspect of the inventive concept, there is provided a semiconductor package including: a first semiconductor chip; a second semiconductor chip; and a bonding structure between the first semiconductor chip and the second semiconductor chip, wherein the bonding structure includes: a first bonding insulating layer on the first semiconductor chip; a first connection pad in a first pad opening in the first bonding insulating layer, the first connection pad including a first pad layer filling the inside of the first pad opening, a first interface layer on an upper surface of the first pad layer, the first interface layer including copper oxide, and a first capping layer on an upper surface of the first interface layer; a second bonding insulating layer on the second semiconductor chip and having a first surface in contact with a first surface of the first bonding insulating layer; and a second connection pad in a second pad opening in the second bonding insulating layer, the second connection pad including a second pad layer within the second pad opening, a second interface layer on an upper surface of the second pad layer, the second interface layer including copper oxide, and a second capping layer on an upper surface of the second interface layer and in contact with the first capping layer, and wherein the first capping layer and the second capping layer include copper monocrystal layers having a (111) orientation.

According to another aspect of the inventive concept, there is provided a semiconductor package including: a first semiconductor chip; a second semiconductor chip on the first semiconductor chip; and a bonding structure between the first semiconductor chip and the second semiconductor chip, wherein the bonding structure includes: a first connection pad including a first pad layer electrically connected to the first semiconductor chip and a first capping layer on an upper surface of the first pad layer; and a second connection pad including a second pad layer electrically connected to the second semiconductor chip and a second capping layer on an upper surface of the second pad layer and in contact with the first capping layer, and wherein the first capping layer and the second capping layer include copper monocrystal layers having a (111) orientation, and each of the first capping layer and the second capping layer has a thickness of about 50 nm to about 1 μm.

According to another aspect of the inventive concept, there is provided a semiconductor package including: a first semiconductor chip; a second semiconductor chip; and a bonding structure between the first semiconductor chip and the second semiconductor chip, wherein the bonding structure includes: a first connection pad including a first pad layer electrically connected to the first semiconductor chip, a first interface layer on an upper surface of the first pad layer and including a copper oxide, and a first capping layer on an upper surface of the first interface layer and formed of a copper monocrystal layer having a (111) orientation; and a second connection pad including a second pad layer electrically connected to the second semiconductor chip, a second interface layer on an upper surface of the second pad layer and including a copper oxide, and a second capping layer on an upper surface of the second interface layer, formed of a copper monocrystal layer having the (111) orientation, and in contact with the first capping layer.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a semiconductor package according to embodiments;

FIG. 2 is an enlarged view of a Region CX1 of FIG. 1;

FIG. 3 is a schematic diagram of a microstructure of a Region CX2 of FIG. 2;

FIG. 4 is a schematic diagram of grain orientation of a first pad layer and a first capping layer of FIG. 3;

FIG. 5 is a cross-sectional view of a semiconductor package according to embodiments;

FIG. 6 is a cross-sectional view of a semiconductor package according to embodiments;

FIG. 7 is a cross-sectional view of a semiconductor package according to embodiments;

FIG. 8 is an enlarged view of a part corresponding to a Region CX1 of FIG. 7;

FIG. 9 is a cross-sectional view of a semiconductor package according to embodiments;

FIG. 10 is an enlarged view of a region CX3 of FIG. 9;

FIG. 11 is a cross-sectional view of a semiconductor package according to embodiments;

FIGS. 12 to 17 are schematic diagrams of a manufacturing method of a semiconductor package according to embodiments; and

FIGS. 18 and 19 are schematic diagrams of a manufacturing method of a semiconductor package according to embodiments.

### DETAILED DESCRIPTION OF THE EMBODIMENTS

Hereinafter, example embodiments of the technical ideas of the inventive concept are described in detail with reference to the accompanying drawings.

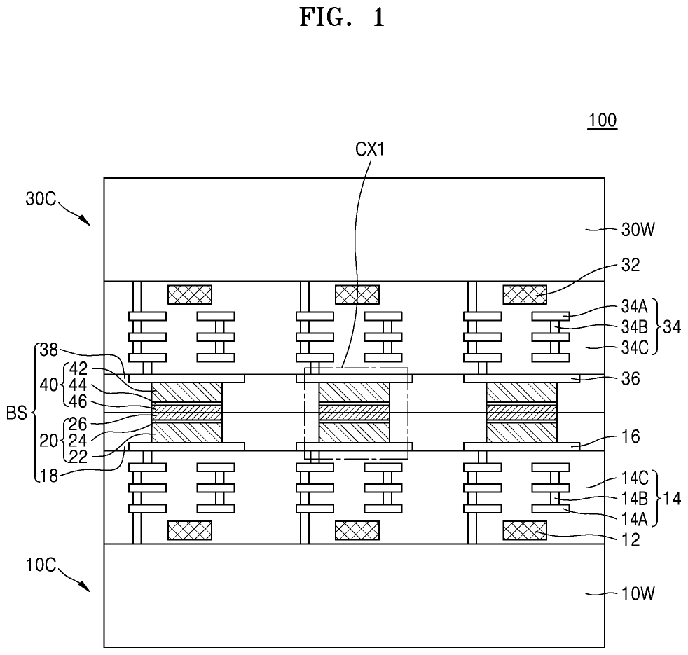

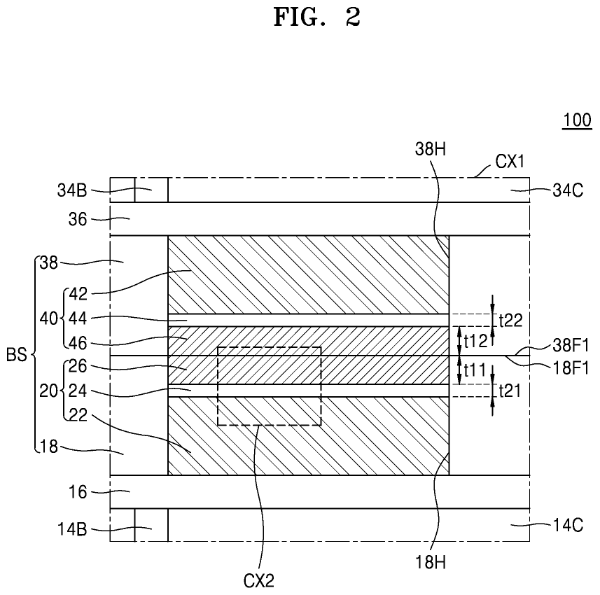

FIG. 1 is a cross-sectional view of a semiconductor package 100 according to embodiments. FIG. 2 is an enlarged view of a Region CX1 of FIG. 1.

With reference to FIGS. 1 and 2, the semiconductor package 100 may have a structure in which a first semiconductor chip 10C is bonded to a second semiconductor chip 30C. The semiconductor package 100 may further include a bonding structure BS formed on an interface of the first semiconductor chip 10C and the second semiconductor chip 30C.

The first semiconductor chip 10C may include a first substrate 10W, a first element layer 12 formed on the first substrate 10W, a first front-end structure 14 covering the first element layer 12, a first bonding insulating layer 18 arranged on the first front-end structure 14, and a first connection pad 20 electrically connected to the first front-end structure 14.

The second semiconductor chip 30C may include a second substrate 30C, a second element layer 32 formed on the second substrate 30W, a second front-end structure 34 covering the second element layer 32, a second bonding insulating layer 38 arranged on the second front-end structure 34, and a second connection pad 40 electrically connected to the second front-end structure 34.

The bonding structure BS may include the first bonding insulating layer 18 and the first connection pad 20 arranged in the first semiconductor chip 10C and the second bonding insulating layer 38 and second connection pad 40 arranged in the second semiconductor chip 30C. As a first side 18F1 (FIG. 2) of the first bonding insulating layer 18 and a first side 38F1 (FIG. 2) of the second bonding insulating layer 38 may be in contact with each other and the first connection pad 20 and the second connection pad 40 are in contact with each other, the first semiconductor chip 10C and the second semiconductor chip 30C may be attached to each other. The first semiconductor chip 10C and the second semiconductor chip 30C may be attached to each other through hybrid bonding of metal oxides by the first bonding insulating layer 18, the first connection pad 20, the second bonding insulating layer 38, and the second connection pad 40.

The first substrate 10W and the second substrate 30W may include a group IV material wafer such as a silicon wafer or a group III-V compound wafer. Also, in terms of a formation method, the first substrate 10W and the second substrate 30W may include a monocrystal wafer, such as a silicon monocrystal wafer. However, the first substrate 10W and the second substrate 30W are not limited to monocrystal wafers, and the first substrate 10W and the second substrate 30W may include various other wafers, such as an epitaxial wafer, a polished wafer, an annealed wafer, a silicon on insulator (SOI) wafer, etc. Here, the epitaxial wafer may refer to a wafer having a silicon substrate on which a crystalline material is grown. In addition, the first substrate 10W and the second substrate 30W may include a well doped with impurities or a structure doped with impurities. Also, the first substrate 10W and the second substrate 30W may include various element isolation structures, such as a shallow trench isolation (STI) structure.

Each of the first and second semiconductor chips 10C and 30C may include a plurality of individual devices of various types. The plurality of individual devices may include microelectronic devices, for example, a metal-oxide-semiconductor field effect transistor (MOSFET), such as a complementary metal-oxide-semiconductor (CMOS) transistor, etc., a system large scale integration (LSI), an image sensor, such as a CMOS imaging sensor (CIS), etc., a micro-electro-mechanical system (MEMS), an active element, a passive element, etc.

In some embodiments, each of the first and second semiconductor chips 10C and 30C may be at least one of a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, and a resistive random access memory (RRAM) chip.

For example, as shown in FIG. 1, the first element layer 12 may be formed on the first substrate lOW and the second element layer 32 may be formed on the second substrate 30W. The first element layer 12 and the second element layer 32 may include various semiconductor devices such as a transistor, a capacitor, a diode, a resistor, etc.

The first front-end structure 14 may be arranged on the first substrate 10W, and may include a plurality of first wiring patterns 14A, a plurality of first contacts 14B, and a first interlayer insulating film 14C. The first element layer 12 may exchange an electrical signal with the outside (i.e., with other elements and/or devices) through the plurality of first wiring patterns 14A and the plurality of first contacts 14B. Here, the electrical signal may include a power supply voltage, a ground voltage, a signal voltage, etc. The plurality of first wiring patterns 14A may have a stacked structure of a plurality of metal layers arranged at different vertical levels, as illustrated in FIG. 1. The first interlayer insulating film 14C may have a stacked structure of a plurality of insulating layers, and the first interlayer insulating film 14C may be arranged to cover the first element layer 12.

The second front-end structure 34 may be arranged on the second substrate 30W, and may include a plurality of second wiring patterns 34A, a plurality of second contacts 34B, and a second interlayer insulating film 34C. The second element layer 32 may exchange an electrical signal with the outside (i.e., with other elements and/or devices) through the plurality of second wiring patterns 34A and the plurality of second contacts 34B. The plurality of second wiring patterns 34A may have a stacked structure of a plurality of metal layers arranged at different vertical levels, as illustrated in FIG. 1. The second interlayer insulating film 34C may have a stacked structure of a plurality of insulating layers, and the second interlayer insulating film 34C may be arranged to cover the second element layer 32.

As shown in FIG. 2, a first landing wiring layer 16 may be arranged on the first front-end structure 14, and the first bonding insulating layer 18 may be arranged to cover the first landing wiring layer 16 and the first front-end structure 14. A first pad opening 18H exposing an upper side of the first landing wiring layer 16 may be formed in the first bonding insulating layer 18, and the first connection pad 20 may be arranged in the first pad opening 18H. An upper side of the first connection pad 20 may be arranged on the same plane as the first side 18F1 of the first bonding insulating layer 18.

Similarly, a second landing wiring layer 36 may be arranged on the second front-end structure 34, and the second bonding insulating layer 38 may be arranged to cover the second landing wiring layer 36 and the second front-end structure 34. A second pad opening 38H exposing an upper side of the second landing wiring layer 36 may be formed in the second bonding insulating layer 38, and the second connection pad 40 may be arranged in the second pad opening 38H. An upper side of the second connection pad 40 may be arranged on the same plane as the first side 38F1 of the second bonding insulating layer 38.

The first side 18F1 of the first bonding insulating layer 18 may be in contact with the first side 38F1 of the second bonding insulating layer 38. The first side 18F1 of the first bonding insulating layer 18 and the first side 38F1 of the second bonding insulating layer 38 may have a flat upper side level and may be attached to each other. Here, a surface of the first connection pad 20 facing the second semiconductor chip 30C may be referred to as an upper side of the first connection pad 20, and a surface of the second connection pad 40 facing the first semiconductor chip 10C may be referred to as an upper side of the second connection pad 40. The upper side of the first connection pad 20 and the upper side of the second connection pad 40 may be in contact with each other.

The first connection pad 20 may include a first pad layer 22, a first interface layer 24, and a first capping layer 26. The first pad layer 22 may be arranged to fill a lower portion of the first pad opening 18H and to be in contact with an upper side of the first landing wiring layer 16. The first interface layer 24 may be arranged to entirely cover an upper side of the first pad layer 22. The first capping layer 26 may be arranged to entirely cover an upper side of the first interface layer 24.

In some embodiments, the first pad layer 22 may include copper (Cu), gold (Au), nickel (Ni), aluminum (Al), tungsten (W), or alloys thereof. For example, the first pad layer 22 may include a copper layer formed by a plating process, and the first pad layer 22 may have a polycrystal microstructure in which a plurality of grains are randomly distributed.

In some embodiments, the first capping layer 26 may be a continuous layer entirely covering the upper side of the first pad layer 22. The first capping layer 26 may include a copper monocrystal layer, and the copper monocrystal layer may have a crystallographic (111) orientation of a face-centered cubic (FCC) crystal structure. For example, the entire upper side of the first capping layer 26 may be oriented parallel to a crystallographic (111) plane, and for example, the first capping layer 26 may not substantially have a grain boundary, and may consist of a single grain.

The first capping layer 26 may have a first thickness t11 in a first direction perpendicular to the first side 18F1 of the first bonding insulating layer 18, and for example, the first thickness t11 of the first capping layer 26 may be about 50 nm to about 1 μm; however, the inventive concept is not limited thereto. In some embodiments, the first thickness t11 of the first capping layer 26 may be about 100 nm to about 500 nm, and in other embodiments, the first thickness t11 of the first capping layer 26 may be about 50 nm to about 200 nm.

In some embodiments, the first capping layer 26 may be a monocrystal layer formed by a sputtering process using a monocrystal copper target. FIG. 2 illustrates that the first thickness t11 of the first capping layer 26 is uniform in the entire region of the first pad opening 18H. However, unlike the illustration of FIG. 2, a thickness of a part of the first capping layer 26 arranged in a central region of the first pad opening 18H may be greater than a thickness of a part of the first capping layer 26 arranged in an edge region of the first pad opening 18H.

In some embodiments, the first interface layer 24 may be conformally arranged between the first pad layer 22 and the first capping layer 26. The first interface layer 24 may include a metal oxide of a metal material included in the first pad layer 22. In some embodiments, the first interface layer 24 may include a copper oxide. The first interface layer 24 may have a second thickness t21 that is less than the first thickness t11 in the first direction. For example, the second thickness t21 of the first interface layer 24 may be about 5 nm to 100 nm, but the inventive concept is not limited thereto.

For example, the first pad layer 22 may be formed in the first pad opening 18H by an electroplating method, and then, an upper portion of the first pad layer 22 may be planarized by a using a chemical mechanical polishing (CMP) process. During the planarization process or after the planarization process, the first interface layer 24 including a copper oxide may be formed through oxidation of an exposed surface of the first pad layer 22 by the atmosphere in the planarization process.

The first bonding insulating layer 18 may include at least one of a silicon oxide, a silicon nitride, and silicon carbon nitride (SiCN). In some embodiments, the first bonding insulating layer 18 may be formed in a stacked structure of a first lower insulating layer (not shown) and a first upper insulating layer (not shown), and an upper side of the first upper insulating layer may be arranged on the same plane as the upper side of the first connection pad 20, and may be attached to the second bonding insulating layer 38. In some embodiments, the first lower insulating layer may include at least one of tetraethyl orthosilicate (TEOS), Tonen SilaZene (TOSZ), ALD oxide, flowable chemical vapor deposition (FCVD) oxide, high density plasma (HDP) oxide, and plasma enhanced oxidation (PEOS) oxide, and the first upper insulating layer may include a silicon carbon nitride; however, the inventive concept is not limited thereto.

The second connection pad 40 may include a second pad layer 42, a second interface layer 44, and a second capping layer 46. The second pad layer 42 may be arranged to fill a lower portion of the second pad opening 38H and to be in contact with an upper side of the second landing wiring layer 36. The second interface layer 44 may be arranged to entirely cover an upper side of the second pad layer 42. The second capping layer 46 may be arranged to entirely cover an upper side of the second interface layer 44.

In some embodiments, the second pad layer 42 may include copper (Cu), gold (Au), nickel (Ni), aluminum (Al), tungsten (W), or alloys thereof. For example, the second pad layer 42 may include a copper layer formed by a plating process, and the second pad layer 42 may have a polycrystal microstructure in which a plurality of grains are randomly distributed.

In some embodiments, the second capping layer 46 may be a continuous layer entirely covering the upper side of the second pad layer 42. The second capping layer 46 may include a copper monocrystal layer, and the copper monocrystal layer may have a crystallographic (111) orientation of an FCC crystal structure. For example, the entire upper side of the second capping layer 46 may be oriented to the crystallographic (111) side, and for example, the second capping layer 46 may not substantially have a grain boundary, and may consist of a single grain.

The second capping layer 46 may have a third thickness t12 in the first direction perpendicular to the first side 18F1 of the first bonding insulating layer 18, and for example, the third thickness t12 of the second capping layer 46 may be about 50 nm to about 1 μm; however, the inventive concept is not limited thereto. For example, the second capping layer 46 may be a monocrystal layer formed by a sputtering process using a monocrystalline target.

In some embodiments, the second interface layer 44 may be conformally arranged between the second pad layer 42 and the second capping layer 46. The second interface layer 44 may include a metal oxide of a metal material included in the second pad layer 42. In some embodiments, the second interface layer 44 may include a copper oxide. The second interface layer 44 may have a fourth thickness t22 that is less than the third thickness t12 in the first direction. For example, the fourth thickness t22 of the second interface layer 44 may be about 5 nm to 100 nm, but the inventive concept is not limited thereto.

The first connection pad 20 and the second connection pad 40 may be bonded by inter-diffusion of metal atoms through high temperature annealing. Further, the first bonding insulating layer 18 and the second bonding insulating layer 38 may be bonded to each other by applying the high-temperature annealing process thereto when they are in contact with each other. The constituent materials of the second bonding insulating layer 38 may be similar to those described above in regard to the first bonding insulating layer 18.

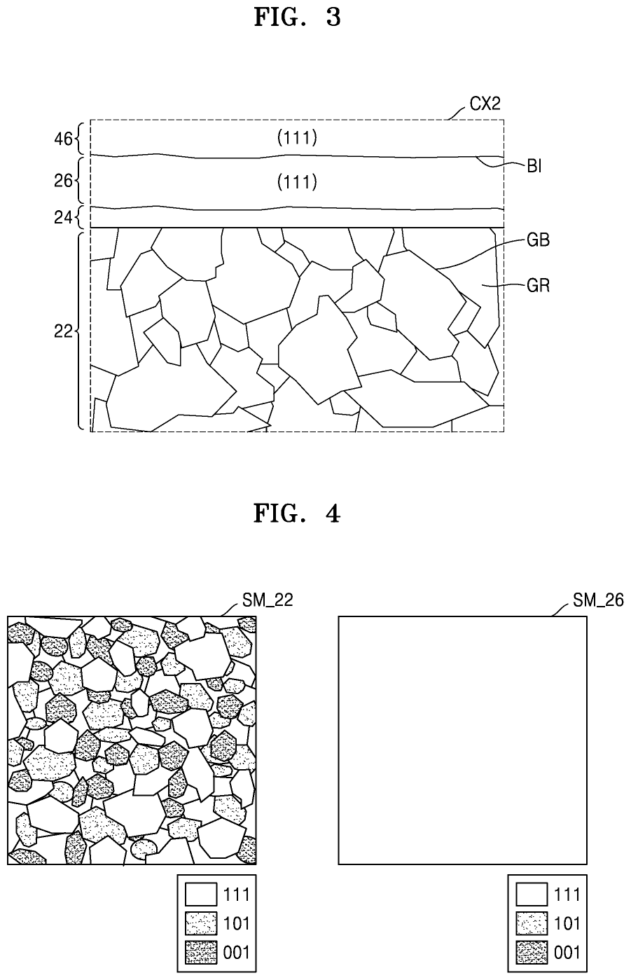

Hereinafter, the microstructure of the first connection pad 20 is described in detail with reference to FIGS. 3 and 4.

FIG. 3 is a schematic diagram of a microstructure of a Region CX2 of FIG. 2. FIG. 4 is a schematic diagram of grain orientation of the first pad layer 22 and the first capping layer 26 of FIG. 3.

With reference to FIG. 3, the first pad layer 22 may have a polycrystal microstructure in which a plurality of grains GR are randomly distributed. The plurality of grains GR may be arranged to be in contact with adjacent grains with respect to a grain boundary GB as an interface, and the size of each of the plurality of grains GR may be randomly distributed.

A first interface layer 24 covering the plurality of grains GR may be arranged on the first pad layer 22, and the first capping layer 26 may be arranged on the first interface layer 24. The first capping layer 26 may be, for example, a monocrystal layer of copper, and an upper side of the first capping layer 26 may be arranged parallel to the (111) side of the copper crystal structure. The first capping layer 26 may not have a grain boundary in the entire region of the first capping layer 26, and may have a relatively flat upper side in the entire region of the first capping layer 26. In some embodiments, the first capping layer 26 may have a surface roughness of about 0.2 nm to about 0.4 nm, but the inventive concept is not limited thereto. Also, the first capping layer 26 may have a resistivity of about 1.6 μΩ·cm to about 2.0 μΩ·cm, but the inventive concept is not limited thereto.

The upper side of the first capping layer 26 may be in contact with an upper side of the second capping layer 46 and form a bonding interface BI. As the first capping layer 26 may have a relatively small surface roughness, the bonding interface BI between the first capping layer 26 and the second capping layer 46 may also have a relatively flat shape. As shown in FIG. 3, the bonding interface BI between the first capping layer 26 and the second capping layer 46 may be identifiable; however, in some embodiments, at least a part of the bonding interface BI between the first capping layer 26 and the second capping layer 46 may not be identifiable.

FIG. 4 schematically illustrates grain orientation of the upper side of the first pad layer 22 and the upper side of the first capping layer 26. For example, an upper side mapping image SM_22 of the first pad layer 22 is illustrated on the left part of FIG. 4, and an upper side mapping image SM_26 of the first capping layer 26 is illustrated on the right part of FIG. 4. The upper side mapping image SM_22 of the first pad layer 22 and the upper side mapping image SM_26 of the first capping layer 26 may respectively illustrate a grain orientation result analyzed by an electron backscatter diffraction (EBSD) method.

For example, as the first pad layer 22 has a polycrystal microstructure in which a plurality of grains GR are randomly distributed, the plurality of grains GR of the first pad layer 22 may have (111) orientation, (101) orientation, and (001) orientation in similar proportion. On the contrary, the first capping layer 26 may have a monocrystal microstructure, and the first capping layer 26 may have (111) orientation in its entire region. For example, the first capping layer 26 may have a content of grains having (111) orientation greater than or equal to 99% as a result of EBSD analysis; however, the inventive concept is not limited thereto.

In general, a process of bonding the first connection pad 20 to the second connection pad 40 is carried out at a high temperature, for example, at about 300° C. to 350° C. to cause a bonding by diffusion of copper atoms. In the process of forming the first connection pad 20 and the second connection pad 40, the first pad layer 22 and the second pad layer 42 may be formed by a plating process, and the upper sides of the first pad layer 22 and the second pad layer 42 may be removed by a CMP process. However, in this CMP process, the first and second interface layers 24 and 44 may be formed on the upper sides of the first pad layer 22 and the second pad layer 42 in a relatively large thickness. As the first and second interface layers 24 and 44 include a copper oxide, when the first and second interface layers 24 and 44 are formed in an excessively large thickness, the diffusion of the copper atoms from the first and second interface layers 24 and 44 may become difficult. Accordingly, the process of bonding the first connection pad 20 to the second connection pad 40 may be carried out at a relatively high temperature of about 300° C. to 350° C.

However, according to the embodiments described with reference to FIGS. 1 to 4, as the first capping layer 26 includes the (111) monocrystal layer, the bonding process of the first capping layer 26 and the second capping layer 46 may be performed at a relatively low temperature. For example, the diffusivity of copper atoms through (111) grains is known to be about 10 to 1000 times greater than the diffusivity of copper atoms through (001) grains or (101) grains. As the first capping layer 26 and the second capping layer 46 are formed of the (111) monocrystal layer, the copper atoms may be diffused relatively easily in the process of bonding the first connection pad 20 to the second connection pad 40, and accordingly, the bonding process may be performed at a relatively low temperature, e.g., about 150° C. to 250° C.

Further, the first capping layer 26 and the second capping layer 46 may have a relatively smooth surface, and may have a relatively low surface roughness. Therefore, the bonding interface BI of the first capping layer 26 and the second capping layer 46 may have a relatively flat shape, and the bonding structure BS may have a low contact resistance.

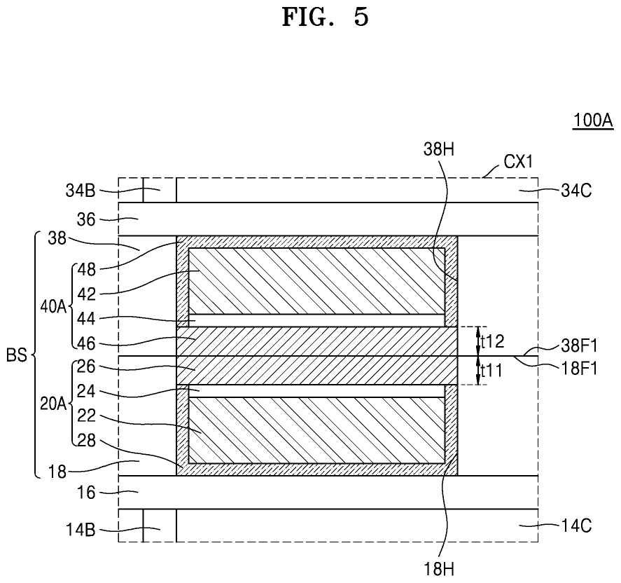

FIG. 5 is a cross-sectional view of a semiconductor package 100A according to embodiments. FIG. 5 is an enlarged view of a part corresponding to a Region CX1 of FIG. 1. In FIG. 5, the reference numerals that are the same as those in FIGS. 1 to 4 denote the same components as in FIGS. 1 to 4.

With reference to FIG. 5, a first connection pad 20A may further include a first conductive barrier layer 28 conformally arranged on an inner wall of the first pad opening 18H, as illustrated. The first conductive barrier layer 28 may be arranged between the first pad layer 22 and the first bonding insulating layer 18 and between the first pad layer 22 and the first landing wiring layer 16, as illustrated.

A second connection pad 40A may further include a second conductive barrier layer 48 conformally arranged on an inner wall of the second pad opening 38H, as illustrated. The second conductive barrier layer 48 may be arranged between the second pad layer 42 and the second bonding insulating layer 38 and between the second pad layer 42 and the second landing wiring layer 36, as illustrated.

In some embodiments, the first and second conductive barrier layers 28 and 48 may include at least one of titanium (Ti), tantalum (Ta), titanium nitride (TiN), and tantalum nitride (TaN).

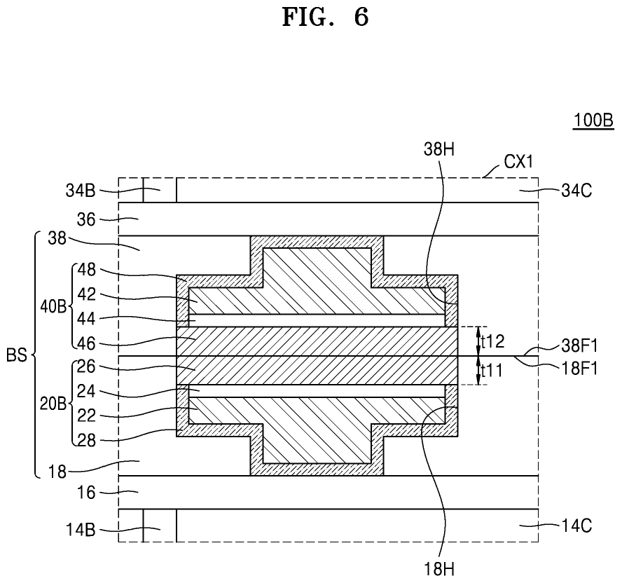

FIG. 6 is a cross-sectional view of a semiconductor package 100B according to embodiments. FIG. 6 is an enlarged view of a part corresponding to the Region CX1 of FIG. 1. In FIG. 6, the reference numerals that are the same as those in FIGS. 1 to 5 denote the same components as in FIGS. 1 to 5.

With reference to FIG. 6, a first connection pad 20B and a second connection pad 40B may be formed through a dual damascene process. The widths of the lower parts of the first connection pad 20B and the second connection pad 40B may be narrow, while the widths of the upper parts of the first connection pad 20B and the second connection pad 40B may be wide, as illustrated (i.e., the width of the upper part of each of the first connection pad 20B and the second connection pad 40B is greater than the width of the lower part of each of the first connection pad 20B and the second connection pad 40B). As the contact area of the first connection pad 20B and the second connection pad 40B may become wider, a stronger bonding may be maintained.

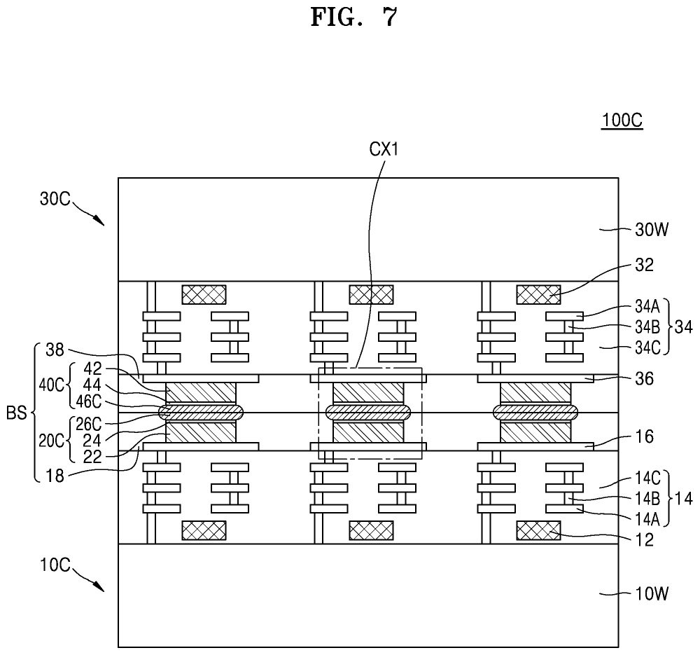

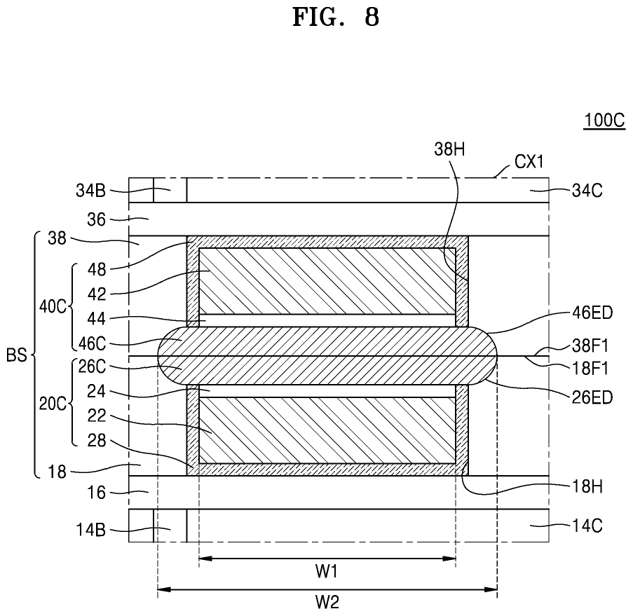

FIG. 7 is a cross-sectional view of a semiconductor package 100C according to embodiments. FIG. 8 is an enlarged view of a part corresponding to a Region CX1 of FIG. 7. In FIGS. 7 and 8, the reference numerals that are the same as those in FIGS. 1 to 6 denote the same components as in FIGS. 1 to 6.

With reference to FIGS. 7 and 8, a first connection pad 20C may have a first capping layer 26C which protrudes outwards more than a side wall of the first pad layer 22, as illustrated. For example, an edge 26ED of the first capping layer 26C may protrude outwards with respect to the side wall of the first pad layer 22 or a side wall of the first conductive barrier layer 28, and the edge 26ED of the first capping layer 26C may be arranged on an upper side of the first bonding insulating layer 18, as illustrated. The first pad layer 22 may have a first width W1 in the horizontal direction, and the first capping layer 26C may have a second width W2 that is greater than the first width W1 in the horizontal direction.

A second connection pad 40C may have a second capping layer 46C which protrudes outwards more than a side wall of the second pad layer 42, as illustrated. For example, an edge 46ED of the second capping layer 46C may protrude outwards with respect to the side wall of the second pad layer 42 or a side wall of the second conductive barrier layer 48, and the edge 46ED of the second capping layer 46C may be arranged on an upper side of the second bonding insulating layer 38, as illustrated.

In the manufacturing process according to some embodiments, the first capping layer 26C may be formed on a structure in which the first pad layer 22 and the first interface layer 24 are formed through a sputtering process. A width of a mask (not shown) used in such a sputtering process may be greater than the width of the first pad layer 22, and in such a case, the first capping layer 26C may be formed to protrude outwards with respect to the side wall of the first pad layer 22. As the first capping layer 26C may be formed to be wider than the first pad layer 22, the contact area of the first connection pad 20C and the second connection pad 40C may become wider, and accordingly, a stronger bonding may be maintained.

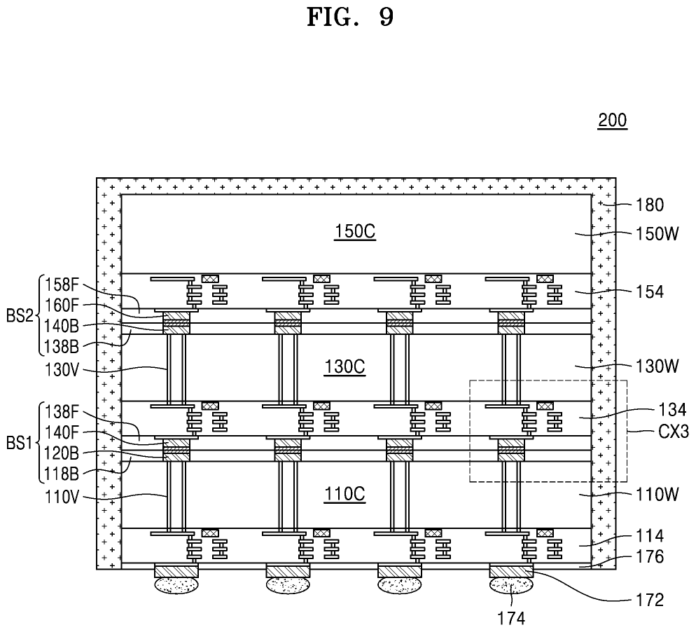

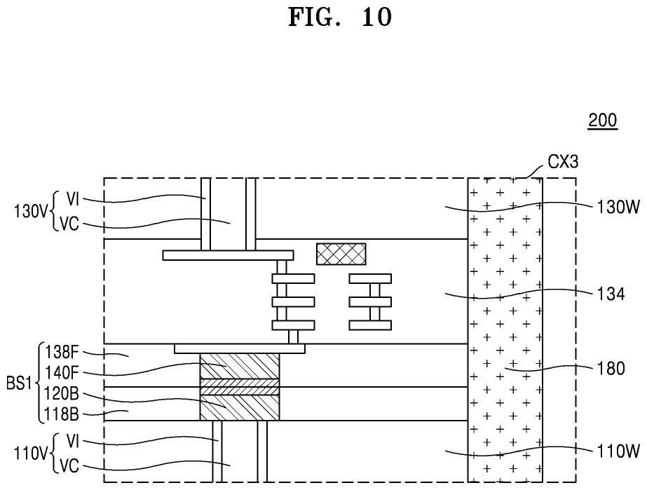

FIG. 9 is a cross-sectional view of a semiconductor package 200 according to embodiments. FIG. 10 is an enlarged view of a region CX3 of FIG. 9.

With reference to FIGS. 9 and 10, the semiconductor package 200 may include a first semiconductor chip 110C, a second semiconductor chip 130C, and a third semiconductor chip 150C. A first bonding structure BS1 may be arranged on an interface between the first semiconductor chip 110C and the second semiconductor chip 130C, and a second bonding structure BS2 may be arranged on an interface between the second semiconductor chip 130C and the third semiconductor chip 150C.

The first semiconductor chip 110C may include a first substrate 110W, a first front-end structure 114 attached to a front side of the first substrate 110W, a through via electrode 110V penetrating the first substrate 110W, a first bonding insulating layer 118B attached to a rear side of the first substrate 110W, and a first connection pad 120B. The through via electrode 110V may include a via conductive layer VC which penetrates the first substrate 110W and a via insulating layer VI surrounding a side wall of the via conductive layer VC. As shown in FIG. 9, the first connection pad 120B may be directly connected to the through via electrode 110V. Alternatively, the first connection pad 120B may be electrically connected to the through via electrode 110V through a wiring layer (not shown).

Similarly, the second semiconductor chip 130C may include a second substrate 130W, a second front-end structure 134 attached to a front side of the second substrate 130W, a second bonding insulating layer 138F attached to the front side of the second substrate 130W, a second connection pad 140F, a through via electrode 130V penetrating the second substrate 130W, a rear-end bonding insulating layer 138B attached to a rear side of the second substrate 130W, and a rear-end connection pad 140B.

The first bonding structure BS1 may include the first bonding insulating layer 118B and the first connection pad 120B arranged in the first semiconductor chip 110C and the second bonding insulating layer 138F and the second connection pad 140F arranged in the second semiconductor chip 130C. The first semiconductor chip 110C and the second semiconductor chip 130C may be bonded by the first bonding structure BS1.

The third semiconductor chip 150C may include a third substrate 150W, a third front-end structure 154 attached to a front side of the third substrate 150W, a third bonding insulating layer 158F attached to the front side of the third substrate 150W, and a third connection pad 160F. For example, the second bonding structure BS2 may include the rear-end bonding insulating layer 138B and the rear-end connection pad 140B arranged in the second semiconductor chip 130C and the third bonding insulating layer 158F and the third connection pad 160F arranged in the third semiconductor chip 150C. The second semiconductor chip 130C and the third semiconductor chip 150C may be bonded by the second bonding structure BS2.

The first bonding structure BS1 and the second bonding structure BS2 may have characteristics similar to those of the bonding structure BS included in any one of the semiconductor packages 100, 100A, 100B, and 100C described above with reference to FIGS. 1 to 8.

A lower pad 172 may be arranged on a front side of the first semiconductor chip 110C, and a connection bump 174 may be attached on the lower pad 172. A passivation layer 176 may be further arranged on the front side of the first semiconductor chip 110C. A molding layer 180 may be arranged to surround lateral sides of the first to third semiconductor chips 110C, 130C, and 150C. The molding layer 180 may include an epoxy mold compound (EMC), etc.

In some embodiments, the first to third semiconductor chips 110C, 130C, and 150C may be memory chips or logic chips. For example, the first to third semiconductor chips 110C, 130C, and 150C may all be memory chips of the same type, or at least one of the first to third semiconductor chips 110C, 130C, and 150C may be a logic chip while the others of the first to third semiconductor chips 110C, 130C, and 150C may be memory chips.

FIG. 9 illustrates that the first to third semiconductor chips 110C, 130C, and 150C are stacked in the vertical direction, and the third semiconductor chip 150C, which is arranged at the top of the stacked structure, does not have a through via electrode. However, in other embodiments, the third semiconductor chip 150C may have a through via electrode, and additional semiconductor chips may be attached on the third semiconductor chip 150C.

Although it is not shown in the drawings, a base substrate (not shown) may be further arranged so that the base substrate and the connection bump 174 may be connected to each other.

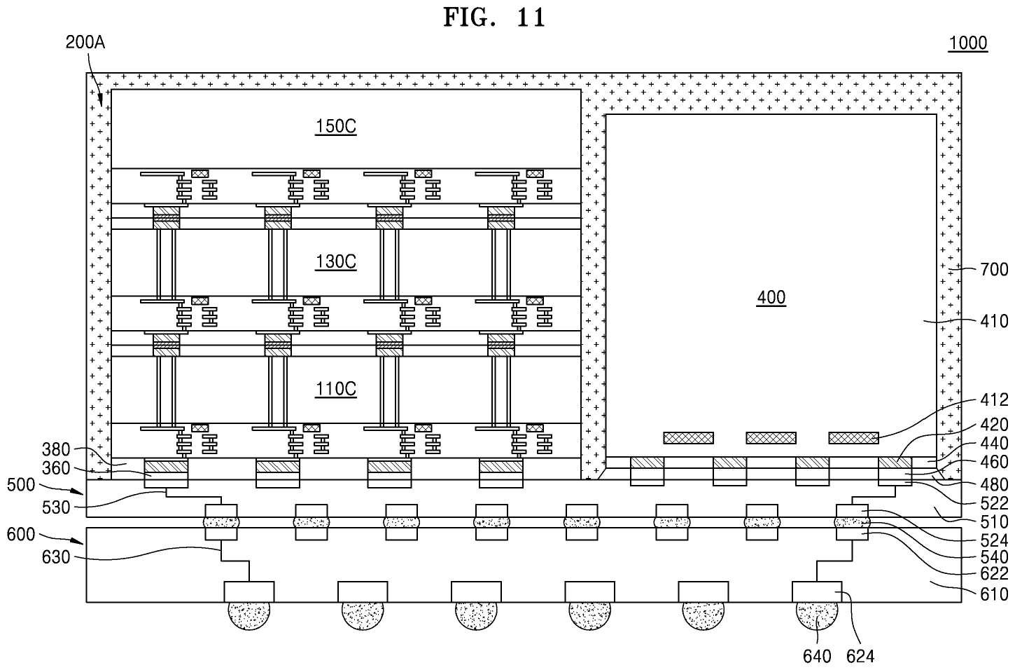

FIG. 11 is a cross-sectional view of a semiconductor package 1000 according to embodiments.

With reference to FIG. 11, the semiconductor package 1000 may include a main board 600 on which an interposer 500 is mounted, a sub-semiconductor package 200A including the first to third semiconductor chips 110C, 130C, and 150C attached to the interposer 500, and a fourth semiconductor chip 400. The sub-semiconductor package 200A may be the semiconductor package 200 described with reference to FIGS. 9 and 10. In addition, the semiconductor package 1000 may be referred to as a system.

Although FIG. 11 illustrates that the semiconductor package 1000 includes one sub-semiconductor package 200A, the inventive concept is not limited thereto. For example, the semiconductor package 1000 may include two or more sub-semiconductor packages 200A.

The fourth semiconductor chip 400 may include a fifth substrate 410 having a third semiconductor device 412 formed on its active surface, a plurality of upper-side connection pads 420, a front-end protection layer 440, and a plurality of connection bumps 460 attached on the plurality of upper-side connection pads 420. The fourth semiconductor chip 400 may be, for example, a central processing unit (CPU) chip, a graphics processing unit (GPU) chip, or an application processor (AP) chip. Each of the plurality of upper-side connection pads 420 may include at least one of aluminum, copper, and nickel.

The interposer 500 may include a base layer 510, a first upper-side pad 522 and a first lower-side pad 524 arranged on an upper side and a lower side of the base layer 510, respectively, and a first wiring route 530 electrically connecting the first upper-side pad 522 to the first lower-side pad 524 through the base layer 510.

The base layer 510 may include a semiconductor, glass, ceramic, or plastic. For example, the base layer 510 may include silicon. The first wiring route 530 may include an internal wiring layer electrically connected to the first upper-side pad 522 and/or the first lower-side pad 524 on the upper side and/or the lower side of the base layer 510. The first wiring route 530 may also include an internal through electrode electrically connecting the first upper-side pad 522 and the first lower-side pad 524 in the base layer 510. The first upper-side pad 522 may be connected to a connection bump 360 electrically connecting the sub-semiconductor package 200A to the interposer 500, and a connection bump 460 electrically connecting the fourth semiconductor chip 400 to the interposer 500.

A first underfill layer 380 may be arranged between the sub-semiconductor package 200A and the interposer 500, and a second underfill layer 480 may be arranged between the fourth semiconductor chip 400 and the interposer 500. The first underfill layer 380 and the second underfill layer 480 may surround the connection bump 360 and the connection bump 460, respectively.

A semiconductor package 1000 may further include a package molding layer 700 surrounding lateral sides of the sub-semiconductor package 200A and the fourth semiconductor chip 400 on the interposer 500. The package molding layer 700 may include, for example, an epoxy mold compound (EMC). In some embodiments, the package molding layer 700 may cover upper sides of the sub-semiconductor package 200A and the fourth semiconductor chip 400. In other embodiments, the package molding layer 700 may not cover upper sides of the sub-semiconductor package 200A and the fourth semiconductor chip 400. For example, a heat dissipation member may be attached on the sub-semiconductor package 200A and the fourth semiconductor chip 400 with a thermal interface material (TIM) layer therebetween. The TIM layer may be, for example, mineral oil, grease, gap filler putty, phase change gel, phase change material pads or particle filled epoxy. The heat dissipation member may be, for example, a heat sink, a heat spreader, a heat pipe, or a liquid cooled cold plate.

A board connection terminal 540 may be attached on the first lower-side pad 524. The board connection terminal 540 may electrically connect the interposer 500 to the main board 600.

The main board 600 may include a base board layer 610, a second upper-side pad 622, and a second lower-side pad 624 arranged on an upper side and a lower side of the base board layer 610, respectively, and a second wiring route 630 electrically connecting the second upper-side pad 622 to the second lower-side pad 624 through the base layer 610, as illustrated.

In some embodiments, the main board 600 may be a printed circuit board. For example, the main board 600 may be a multi-layer printed circuit board. The base board layer 610 may include at least one material selected from phenol resin, epoxy resin, and polyimide.

A solder resist layer (not shown) exposing the second upper-side pad 622 and the second lower-side pad 624 may be formed on each of the upper side and the lower side of the base board layer 610. The board connection terminal 540 may be connected to the second upper-side pad 622, and an external connection terminal 640 may be connected to the second lower-side pad 624. The board connection terminal 540 may electrically connect the first lower-side pad 524 and the second upper-side pad 622. The external connection terminal 640 connected to the second lower-side pad 624 may connect the semiconductor package 1000 to the outside (i.e., to other elements and/or devices).

In some embodiments, the semiconductor package 1000 may not include the main board 600, and the board connection terminal 540 of the interposer 500 may function as the external connection terminal.

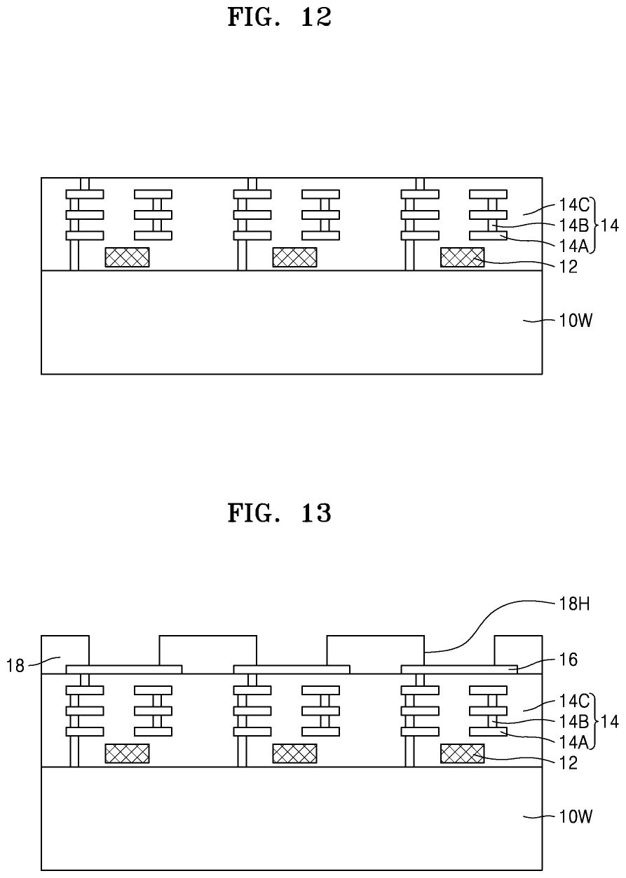

FIGS. 12 to 17 are schematic diagrams of a manufacturing method of the semiconductor package 100 according to embodiments.

With reference to FIG. 12, the first element layer 12 and the first front-end structure 14 may be formed on the first substrate 10W. Although it is not shown in the drawings, the first substrate 10W may include a plurality of chip regions (not shown) spaced apart from each other by a scribe lane region (not shown), and the first element layer 12 may be arranged in each of the chip regions. That is, the first substrate 10W may be provided as a semiconductor wafer.

In some embodiments, although it is not shown, a through via electrode (not shown) extending into the first substrate 10W may be further formed.

With reference to FIG. 13, the first landing wiring layer 16 and the first bonding insulating layer 18 covering the first landing wiring layer 16 may be formed on the first front-end structure 14 by using a conductive material.

In some embodiments, the first bonding insulating layer 18 may be formed through a chemical vapor deposition (CVD) process, an atomic layer deposition (ALD) process, a spin coating process, etc., by using at least one of a silicon oxide, a silicon nitride, and a silicon carbon nitride.

In some embodiments, the first bonding insulating layer 18 may be formed in a stacked structure of a first lower insulating layer (not shown) and a first upper insulating layer (not shown). The first lower insulating layer may be formed by using at least one of TEOS, TOSZ, ALD oxide, FCVD oxide, HDP oxide, and PEOX oxide, and the first upper insulating layer may be formed by using a silicon carbon nitride.

Then, by removing a part of the first bonding insulating layer 18, the first pad opening 18H exposing an upper side of the first landing wiring layer 16 may be formed.

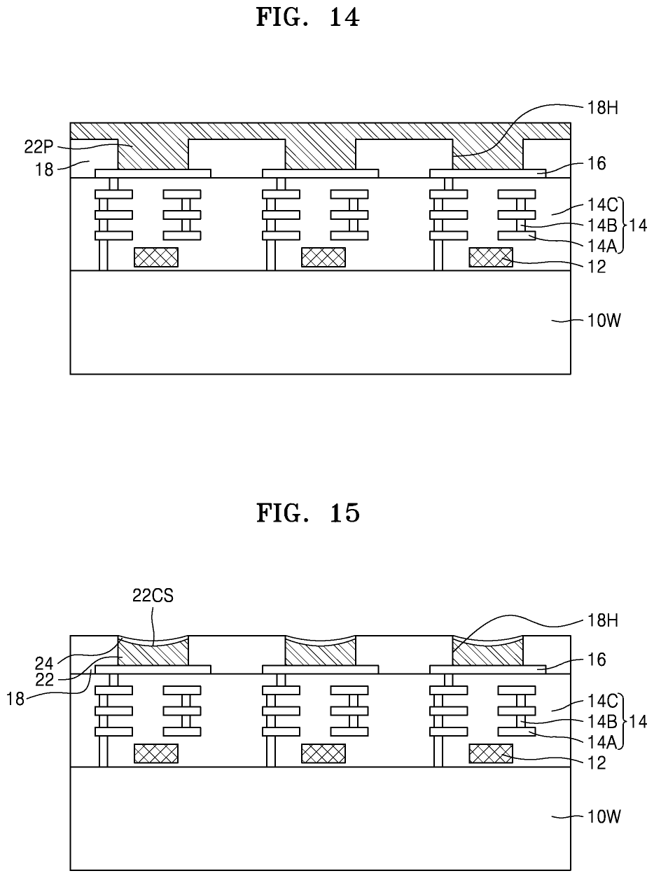

With reference to FIG. 14, a preliminary pad layer 22P with a thickness sufficient to fill the inside of the first pad opening 18H may be formed on the first bonding insulating layer 18. The preliminary pad layer 22P may be formed by using copper (Cu), gold (Au), nickel (Ni), aluminum (Al), tungsten (W), or combinations thereof. In some embodiments, the preliminary pad layer 22P may be formed by a plating process, but the inventive concept is not limited thereto. In some embodiments, before forming the preliminary pad layer 22P, a seed metal layer (not shown) may be formed on the inner wall of the first pad opening 18H, and the preliminary pad layer 22P filling the inside of the first pad opening 18H may be formed with the seed metal layer as a seed material.

In other embodiments, before forming the preliminary pad layer 22P, the first conductive barrier layer 28 (FIGS. 5 and 6) may be formed conformally on the inner wall of the first pad opening 18H. In such a case, the semiconductor package 100A described with reference to FIG. 3 may be manufactured.

With reference to FIG. 15, by performing a chemical mechanical polishing process or a wet etching process on the preliminary pad layer 22P, an upper side of the preliminary pad layer 22P may be planarized, and the first pad layer 22 may be formed in the first pad opening 18H.

The first interface layer 24 may be formed on the upper side of the first pad layer 22 exposed by the planarization process. For example, when the first pad layer 22 includes copper, and a surface of the first pad layer 22 is exposed to the oxidizing atmosphere or air, the first interface layer 24 may include copper oxides formed by oxidation of copper atoms of the surface.

In some embodiments, after the planarization process, an upper side 22CS of the first pad layer 22 may be arranged in the central region of the first pad opening 18H at a lower vertical level than in the edge region of the first pad opening 18H, but the inventive concept is not limited thereto.

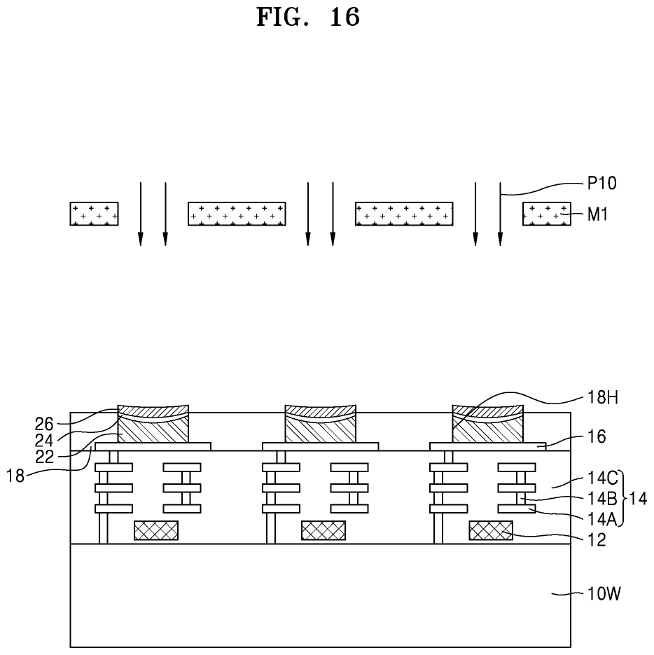

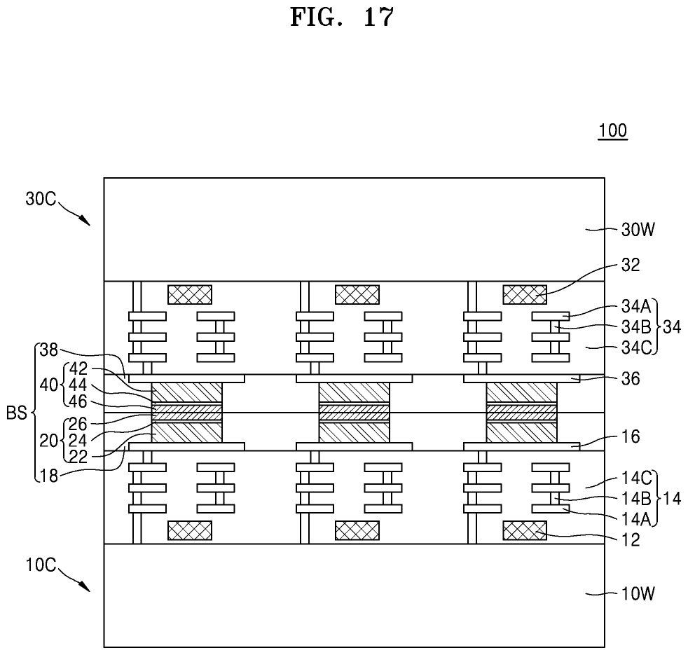

With reference to FIG. 16, the first capping layer 26 may be formed on the first pad layer 22. The first capping layer 26 may be formed conformally to entirely cover an upper side of the first interface layer 24 arranged on the upper side of the first pad layer 22, as illustrated.

In some embodiments, the first capping layer 26 may be formed by a sputtering process P10 using a first mask M1. The first mask M1 may include an opening (not shown) which vertically overlaps the first pad opening 18H. For example, the sputtering process P10 may be performed using a monocrystal copper target. For example, the monocrystal copper target may have a monocrystal (111) orientation. In a process chamber, sputtering gases such as argon, nitrogen, etc. may collide with the monocrystal copper target, and monocrystal copper atoms or clusters separated from the monocrystal copper target due to the collision may pass through the first mask M1 and then be deposited on the first substrate 10W.

In some embodiments, the first capping layer 26 may be formed to have (111) orientation of the FCC crystal structure of copper, and may be formed to be a continuous monocrystal layer entirely covering upper sides of the first pad layer 22 and the first interface layer 24.

Here, the first capping layer 26 is described as being formed by the sputtering process P10 as an example, but the technical ideas of the inventive concept are not limited thereto. In other embodiments, the first capping layer 26 may be formed to have a monocrystal (111) orientation by evaporation, molecular beam epitaxy, CVD, ALD, etc.

As the first capping layer 26 is formed to have the monocrystal (111) orientation, the first capping layer 26 may have a smooth surface and have a surface roughness of, for example, about 0.2 nm to about 0.4 nm. Further, as the first capping layer 26 is formed to have the monocrystal (111) orientation, the first capping layer 26 may have a relatively low resistivity of about 1.6 μΩ·cm to about 2.0 μΩ·cm.

By performing the process described with reference to FIGS. 12 to 17, a structure in which the second bonding insulating layer 38, the second pad layer 42, the second interface layer 44, and the second capping layer 46 are formed on the second substrate 30W may also be formed.

With reference to FIG. 17, the second substrate 30W may be attached on the first substrate 10W.

In some embodiments, the bonding process may be carried out when the first bonding insulating layer 18 on the first substrate 10W and the second bonding insulating layer 38 on the second substrate 30W are in contact with each other, and the first capping layer 26 on the first substrate 10W and the second capping layer 46 on the second substrate 30W are in contact with each other. The temperature of the bonding process may be about 150° C. to 250° C., but the inventive concept is not limited thereto. By the bonding process, the upper side of the first bonding insulating layer 18 and the upper side of the second bonding insulating layer 38 may be attached to each other, and the upper side of the first capping layer 26 and the upper side of the second capping layer 46 may be attached to each other.

As the first capping layer 26 and the second capping layer 46 are formed of the (111) monocrystal layer, the copper atoms may be diffused relatively easily in the process of bonding the first connection pad 20 to the second connection pad 40, and accordingly, the bonding process may be performed at a relatively low temperature, e.g., about 150° C. to 250° C. Further, as the first capping layer 26 and the second capping layer 46 may have a smooth surface, and have a relatively low surface roughness, the bonding interface BI between the first capping layer 26 and the second capping layer 46 may have a relatively flat shape (see FIG. 4.)

Then, by a grinding process, some of the thickness of the second substrate 30W may be removed, and a bonded structure of the first substrate lOW and the second substrate 30W may be sawed along the scribe lane. In this manner, the semiconductor package 100 in which the first semiconductor chip 10C and the second semiconductor chip 30C are stacked may be manufactured.

According to some embodiments, before bonding the second substrate 30W on the first substrate 10W, the second substrate 30W may be attached to a carrier substrate (not shown), and some of the thickness of the second substrate 30W may be removed by the grinding process, which facilitates singulation into the second semiconductor chip 30C. Then, by arranging the second semiconductor chip 30C on the first substrate 10W and performing the bonding process, the second semiconductor chip 30C may be attached on the first substrate 10W. Next, by sawing the first substrate 10W along the scribe lane region, the semiconductor package 100 in which the first semiconductor chip 10C and the second semiconductor chip 30C are stacked may be manufactured.

According to other embodiments described with reference to FIGS. 9 and 10, after attaching the second semiconductor chip 130C on the first substrate 110W by arranging the second semiconductor chip 130C on the first substrate 110W and performing the bonding process, the rear-end bonding insulating layer 138B and the rear-end connection pad 140B may be formed on a rear side (the opposite side to the front-end structure 134 of the second semiconductor chip 130C) of the second semiconductor chip 130C. At this time, the rear-end connection pad 140B may be arranged to be electrically connected to a second through via electrode 130V. Then, after arranging the third semiconductor chip 150C on the rear side of the second semiconductor chip 130C, the bonding process may be performed. In this manner, the semiconductor package 200 described with reference to FIGS. 9 and 10 may be manufactured.

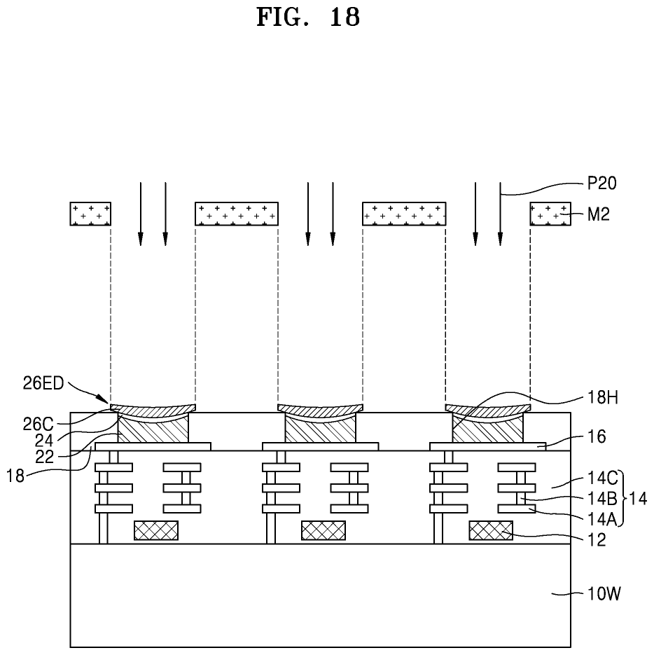

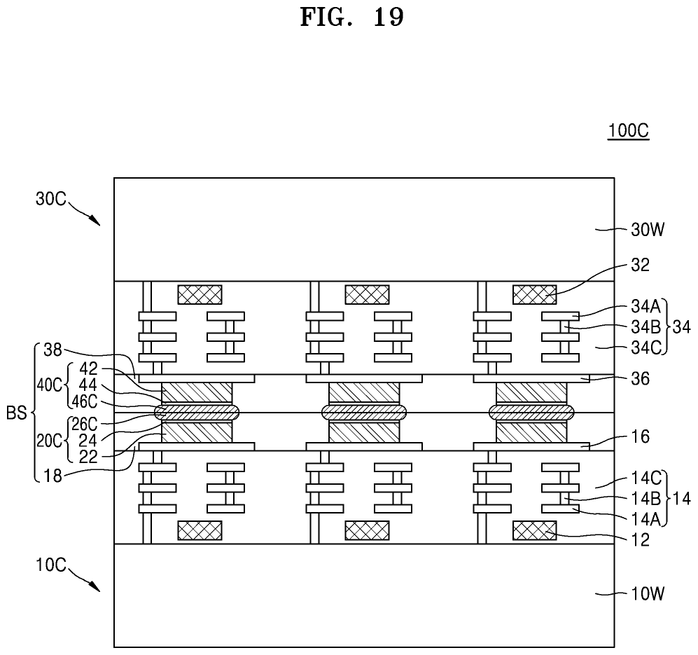

FIGS. 18 and 19 are schematic diagrams of a manufacturing method of a semiconductor package 100C according to embodiments.

By performing the process described with reference to FIGS. 12 to 15, a structure in which the first pad layer 22 is formed may be formed.

With reference to FIG. 18, the first capping layer 26C may be formed on the first pad layer 22 by a sputtering process P20 using a second mask M2.

In some embodiments, the second mask M2 may include an opening (not shown) which vertically overlaps the first pad opening 18H and a part of the first bonding insulating layer 18 around the first pad opening 18H. The first capping layer 26C may be formed to have a width W2 (see FIG. 8) greater than a width W1 (see FIG. 8) of the first pad layer 22. The first capping layer 26C may entirely cover the upper side of the first interface layer 24 arranged on the upper side of the first pad layer 22 and extend onto the first bonding insulating layer 18. For example, an edge 26ED of the first capping layer 26C may protrude outwards with respect to the side wall of the first pad layer 22 or a side wall of the first conductive barrier layer 28, and the edge 26ED of the first capping layer 26C may be arranged on an upper side of the first bonding insulating layer 18.

With reference to FIG. 19, the second substrate 30W may be attached on the first substrate 10W. The bonding process may be carried out when the first bonding insulating layer 18 on the first substrate 10W and the second bonding insulating layer 38 on the second substrate 30W are in contact with each other, and the first capping layer 26C on the first substrate lOW and the second capping layer 46C on the second substrate 30W are in contact with each other.

Then, by performing the process described with reference to FIG. 17, the semiconductor package 100C may be completed.

While the inventive concept has been particularly shown and described with reference to embodiments thereof, it will be understood that various changes in form and details may be made therein without departing from the scope of the following claims.

What is claimed is:

1. A semiconductor package comprising:
a first semiconductor chip;
a second semiconductor chip; and
a bonding structure between the first semiconductor chip and the second semiconductor chip,
wherein the bonding structure comprises:
a first bonding insulating layer on the first semiconductor chip;
a first connection pad in a first pad opening in the first bonding insulating layer, the first connection pad comprising a first pad layer within the first pad opening, a first interface layer on an upper surface of the first pad layer, the first interface layer comprising copper oxide, and a first capping layer on an upper surface of the first interface layer;
a second bonding insulating layer on the second semiconductor chip and comprising a first surface in contact with a first surface of the first bonding insulating layer; and
a second connection pad in a second pad opening in the second bonding insulating layer, the second connection pad comprising a second pad layer within the second pad opening, a second interface layer on an upper surface of the second pad layer, the second interface layer comprising copper oxide, and a second capping layer on an upper surface of the second interface layer and in contact with the first capping layer, and
wherein the first capping layer and the second capping layer comprise copper monocrystal layers having a (111) orientation.

2. The semiconductor package of claim 1, wherein each of the first capping layer and the second capping layer has a thickness of about 50 nm to about 1 μm.

3. The semiconductor package of claim 1, wherein each of the first pad layer and the second pad layer comprises a plurality of grains distributed randomly,
the first capping layer comprises a continuous layer on the upper surface of the first pad layer, and
the second capping layer comprises a continuous layer on the upper surface of the second pad layer.

4. The semiconductor package of claim 1, wherein a surface of each of the first capping layer and the second capping layer is configured to have a content of grains having an (111) orientation greater than or equal to 99% in response to an electron backscatter diffraction (EBSD) analysis.

5. The semiconductor package of claim 1, wherein a first surface of the first capping layer is in a same plane as the first surface of the first bonding insulating layer, and
a first surface of the second capping layer is in a same plane as the first surface of the second bonding insulating layer, and
wherein an interface between the first capping layer and the second capping layer is in a same plane as an interface between the first bonding insulating layer and the second bonding insulating layer.

6. The semiconductor package of claim 1, wherein the first semiconductor chip comprises:
a first substrate; and
a through via electrode in the first substrate, the through via electrode comprising a via conductive layer that penetrates the first substrate, and a via insulating layer that surrounds a side wall of the via conductive layer, and
wherein the first connection pad is electrically connected to the through via electrode.

7. The semiconductor package of claim 1, wherein a thickness of the first interface layer is less than a thickness of the first capping layer, and
a thickness of the second interface layer is less than a thickness of the second capping layer.

8. The semiconductor package of claim 1, wherein the first pad layer has a first width in a first direction parallel to an upper surface of the first semiconductor chip, and
the first capping layer has a second width in the first direction, wherein the second width is greater than the first width.

9. The semiconductor package of claim 8, wherein an edge of the first capping layer protrudes outwards with respect to a side wall of the first pad layer, and
the edge of the first capping layer is in contact with an upper surface of the first bonding insulating layer.

10. The semiconductor package of claim 1, wherein the first capping layer has a resistivity of about 1.6 μΩ·cm to about 2.0 μΩ·cm.

11. The semiconductor package of claim 1, wherein the first capping layer has a surface roughness of about 0.2 nm to about 0.4 nm.

12. A semiconductor package comprising:
a first semiconductor chip;
a second semiconductor chip on the first semiconductor chip; and
a bonding structure between the first semiconductor chip and the second semiconductor chip,
wherein the bonding structure comprises:
a first connection pad comprising a first pad layer electrically connected to the first semiconductor chip and a first capping layer on an upper surface of the first pad layer; and
a second connection pad comprising a second pad layer electrically connected to the second semiconductor chip and a second capping layer on an upper surface of the second pad layer and in contact with the first capping layer, and
wherein the first capping layer and the second capping layer comprise copper monocrystal layers having a (111) orientation, and wherein each of the first capping layer and the second capping layer has a thickness of about 50 nm to about 1 μm.

13. The semiconductor package of claim 12, wherein the bonding structure further comprises:
a first bonding insulating layer on the first semiconductor chip and comprising a first surface in a same plane as an upper surface of the first connection pad; and
a second bonding insulating layer on the second semiconductor chip and comprising a first surface in contact with the first surface of the first bonding insulating layer, and
wherein the first surface of the second bonding insulating layer is in a same plane as an upper surface of the second connection pad.

14. The semiconductor package of claim 12, wherein the first connection pad further comprises a first interface layer between the first capping layer and the first pad layer, the first interface layer comprising copper oxide, and
the second connection pad further comprises a second interface layer between the second capping layer and the second pad layer, the second interface layer comprising copper oxide.

15. The semiconductor package of claim 12, wherein the first pad layer and the second pad layer comprise a plurality of grains distributed randomly,
the first capping layer comprises a continuous layer on the upper surface of the first pad layer, and
the second capping layer comprises a continuous layer on the upper surface of the second pad layer.

16. The semiconductor package of claim 12, wherein a surface of each of the first capping layer and the second capping layer is configured to have a content of grains having the (111) orientation greater than or equal to 99% in response to an electron backscatter diffraction (EBSD) analysis.

17. The semiconductor package of claim 12, wherein the first pad layer has a first width in a first direction parallel to an upper surface of the first semiconductor chip, and
the first capping layer has a second width in the first direction, wherein the second width is greater than the first width.

18. The semiconductor package of claim 17, wherein an edge of the first capping layer protrudes outwards with respect to a side wall of the first pad layer.

19. A semiconductor package comprising:
a first semiconductor chip;
a second semiconductor chip; and
a bonding structure between the first semiconductor chip and the second semiconductor chip,
wherein the bonding structure comprises:
a first connection pad comprising a first pad layer electrically connected to the first semiconductor chip, a first interface layer on an upper surface of the first pad layer, the first interface layer comprising copper oxide, and a first capping layer on an upper surface of the first interface layer, the first capping layer comprising a copper monocrystal layer having a (111) orientation; and
a second connection pad comprising a second pad layer electrically connected to the second semiconductor chip, a second interface layer on an upper surface of the second pad layer, the second interface layer comprising copper oxide, and a second capping layer on an upper surface of the second interface layer, the second capping layer comprising a copper monocrystal layer having a (111) orientation, and wherein the second capping layer is in contact with the first capping layer.

20. The semiconductor package of claim 19, wherein the bonding structure further comprises:
a first bonding insulating layer on the first semiconductor chip and comprising a first surface in a same plane as an upper surface of the first connection pad; and
a second bonding insulating layer on the second semiconductor chip and comprising a first surface in contact with the first surface of the first bonding insulating layer, and
wherein the first surface of the second bonding insulating layer is in a same plane as an upper surface of the second connection pad.
